(19) United States
(12) Patent Application Publication
(10) Pub. No.: US 2012/0068357 A1
(43) Pub. Date: Mar. 22, 2012

(54) SEMICONDUCTOR DEVICE AND POWER SEMICONDUCTOR DEVICE

(75) Inventors: Yasuhito Saito, Hyogo-ken (JP); Masahiro Shimura, Ishikawa-ken (JP)

(73) Assignee: KABUSHIKI KAISHA TOSHIBA, Tokyo (JP)

(21) Appl. No.: 13/234,890

(22) Filed: Sep. 16, 2011

(30) Foreign Application Priority Data
Sep. 22, 2010 (JP) 2010-211910

(51) Int. Cl. H01L 23/48

(52) U.S. Cl. 257/774; 257/E23.011

(57) ABSTRACT

According to one embodiment, a semiconductor device includes a base, a semiconductor element, an electrode terminal, a connecting member and a joining material. The semiconductor element is mounted on the base. The electrode terminal is provided spaced from the base. The connecting member connects the semiconductor element to the electrode terminal and includes a plurality of through holes provided in one end portion of the connecting member. The one end portion is connected to the semiconductor element. The joining material intervenes between the semiconductor element and the connecting member and penetrates into the plurality of through holes.

### CROSS-REFERENCE TO RELATED APPLICATIONS

This application is based upon and claims the benefit of priority from the prior Japanese Patent Application No. 2010-211910, filed on Sep. 22, 2010; the entire contents of which are incorporated herein by reference.

### FIELD

Embodiments described herein relate generally to a semiconductor device and a power semiconductor device.

### BACKGROUND

A semiconductor device is provided with a chip-state semiconductor element, a package that seals the semiconductor element, and an electrode terminal communicating with the semiconductor element and extending to the outside from the inside of the package. In the package, the semiconductor element and the electrode terminal are connected to each other by a connecting member. In this type of a semiconductor device, in order to handle a large current, for example, a component obtained by working a metal plate into a predetermined shape is used as the connecting member.

However, since there are many chip sizes for the semiconductor element, design and manufacture of the optimal connecting members for all the chip sizes incur an increase in the number of components and a rise in a manufacturing cost.

### BRIEF DESCRIPTION OF THE DRAWINGS

FIGS. 1A and 1B are schematic diagrams illustrating the configuration of a semiconductor device according to a first embodiment;

FIGS. 2A and 2B are schematic diagrams for describing the semiconductor element;

FIGS. 3A and 3B and FIGS. 4A and 4B are schematic sectional diagrams illustrating specific examples of the through holes;

FIGS. 5A to 5C are schematic plan views illustrating a specific example of a semiconductor device in which a through hole is not provided in the connecting member;

FIGS. 6A to 6C are schematic plan views illustrating a specific example of a semiconductor device in which a through hole is provided in the connecting member;

FIG. 7 is a schematic plan view illustrating the configuration of a semiconductor device according to a second embodiment;

FIG. 8 is a schematic plan view illustrating the configuration of a semiconductor device according to a third embodiment;

FIG. 9 is a schematic plan view illustrating the configuration of a semiconductor device according to a fourth embodiment;

FIGS. 10A to 10B are schematic diagrams illustrating the configuration of a power semiconductor device according to a fifth embodiment; and

FIGS. 11A and 11B are schematic diagrams for describing a variation of the connecting member and the electrode terminal.

### DETAILED DESCRIPTION

In general, according to one embodiment, a semiconductor device includes a base, a semiconductor element, an electrode terminal, a connecting member and a joining material. The semiconductor element is mounted on the base. The electrode terminal is provided spaced from the base. The connecting member connects the semiconductor element to the electrode terminal and includes a plurality of through holes provided in one end portion of the connecting member. The one end portion is connected to the semiconductor element. The joining material intervenes between the semiconductor element and the connecting member and penetrates into the plurality of through holes.

In general, according to one embodiment, a power semiconductor device includes a base, a power semiconductor element, an electrode terminal, a connecting member and a joining material. The power semiconductor element is mounted on the base. The electrode terminal is provided spaced from the base. The connecting member connects the power semiconductor element to the electrode terminal and includes a plurality of through holes provided in one end portion of the connecting member. The one end portion is connected to the power semiconductor element. The joining material intervenes between the power semiconductor element and the connecting member and penetrates into the plurality of through holes. The sealing member seals at least the power semiconductor element.

Various embodiments will be described hereinafter with reference to the accompanying drawings.

The drawings are schematic or conceptional and a relationship between the thickness and the width of each portion, the coefficient ratio in size of portions and the like are not necessarily the same as actual ones. Also, even if the same portions are indicated, dimensions and coefficient ratios might be expressed differently depending on the drawings. In the specification of the application and the drawings, components similar to those described in regard to a drawing thereinabove are marked with like reference numerals, and a detailed description is omitted as appropriate.

### First Embodiment

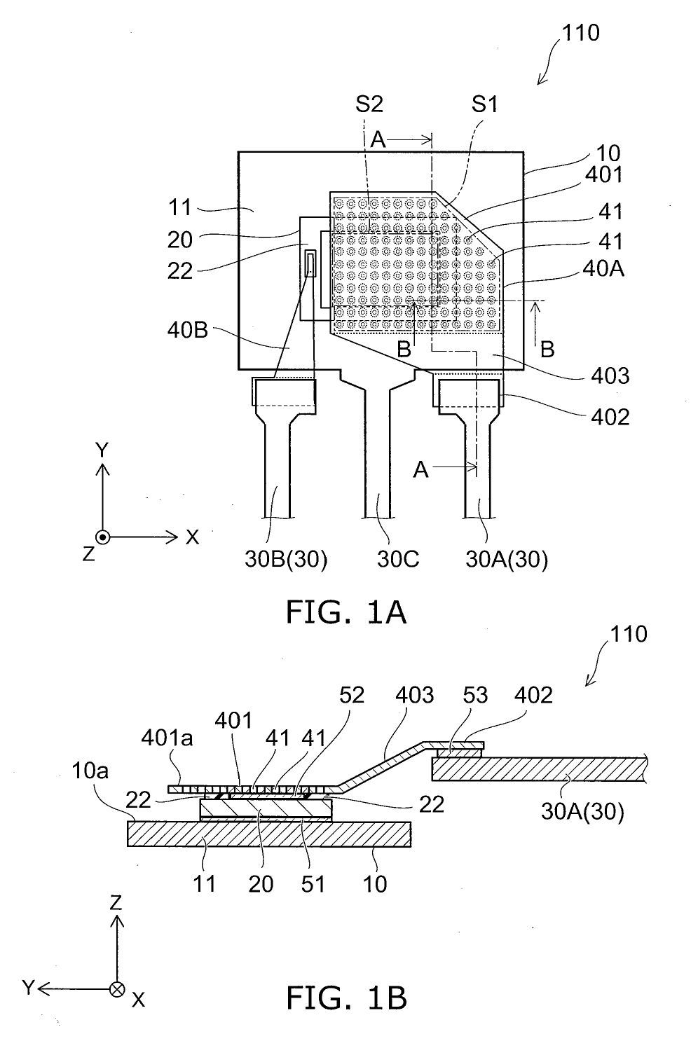

FIGS. 1A and 1B are schematic diagrams illustrating the configuration of a semiconductor device according to a first embodiment.

FIG. 1A is a schematic plan view of the semiconductor device according to the embodiment, and FIG. 1B is a schematic sectional view on arrow of an A-A line shown in FIG. 1A.

That is, as shown in FIGS. 1A and 1B, a semiconductor device 110 according to the embodiment includes a base 10, a semiconductor element 20, an electrode terminal 30A, a connecting member 40A, and joining materials 51, 52, and 53.

In the explanation of the embodiment, it is assumed that one direction along a major surface 10a of the base 10 is the X direction, a direction along the major surface 10a and orthogonal to the X direction is the Y direction, and a direction perpendicular to the major surface 10a is the Z direction.

The base 10 is a frame member that supports the semiconductor element 20 and allows electrical connection. For the base 10, copper (Cu), for example, is used. The base 10 has a pedestal portion 11 on which the semiconductor element 20 is mounted and an electrode terminal 30C extending from the pedestal portion 11. To the pedestal portion 11, the semiconductor element 20 is connected through the joining material 51, which is solder, for example.

On the semiconductor element 20, active elements such as a transistor, a diode and the like and passive elements such as a resistor, a capacitor and the like are formed. The semiconductor element 20 is formed by cutting out a semiconductor substrate and provided in a chip shape. In the semiconductor element 20 illustrated in FIGS. 1A and 1B, electrical connection is made on the back face and the front face, respectively. With regard to the semiconductor element 20, electrical connection is made only on the surface, for example.

The electrode terminal 30A is provided with a distance from the base 10. The electrode terminal 30A illustrated in FIGS. 1A and 1B is arranged with a distance from the pedestal portion 11 of the base 10 so as to extend substantially in parallel with the electrode terminal 30C extending from the pedestal portion 11. In the semiconductor device 110 illustrated in FIGS. 1A and 1B, two electrode terminals 30A and 30B are provided. In the embodiment, the electrode terminals 30A and 30B are collectively referred to as electrode terminals 30.

The number of electrode terminals 30 is not limited to 2, but the electrode terminals are provided in an appropriate number depending on the specifications or the like of the electrode of the semiconductor element 20 or the semiconductor device 110. For the electrode terminal 30, Cu, which is the same as the material of the base 10, for example, is used. The semiconductor device 110 illustrated in FIG. 1 is configured as a device in which three terminals are arranged in the X direction such that the electrode terminal 30C extending in the Y direction from the pedestal portion 11 and the electrode terminals 30A and 30B arranged on the both sides thereof are arranged. For example, if the semiconductor element 20 is MOSFET (Metal-Oxide-Semiconductor Field-Effect Transistor), a gate, a source, and a drain are allocated to the three terminals.

The electrode terminals 30 are connected by the electrode terminal 30C extending from the pedestal portion 11 and a tie bar (not shown), for example, partway the middle of a manufacturing process of the semiconductor device 110. The tie bar is cut off after a sealing member is formed. As a result, the electrode terminals 30 become independent of the electrode terminal 30C.

The connecting member 40A is a member made of metal that allows the semiconductor element 20 to communicate with the electrode terminal 30A. In the semiconductor device 110, if the plurality of electrode terminals 30A and 30B are provided, the connecting member 40A is connected corresponding to the electrode terminal 30A, and a connecting member 40B is connected corresponding to the electrode terminal 30B. If more electrode terminals are provided, the connecting members are connected to the respective electrode terminals.

The connecting member 40A has one end portion 401 connected to the semiconductor element 20, the other end portion 402 connected to the electrode terminal 30A, and an intermediate portion 403 provided between the one end portion 401 and the other end portion 402.

The one end portion 401 is provided substantially in parallel with the surface of the semiconductor element 20. Also, the other end portion 402 is provided substantially in parallel with the surface of the electrode terminal 30A. Also, the intermediate portion 403 is bent with respect to the one end portion 401 and the other end portion 402 as necessary, and a difference is given in the height in the Z direction between the one end portion 401 and the other end portion 402.

In the semiconductor device 110 of the embodiment, a plurality of through holes 41 are provided in the one end portion 401 of the connecting member 40A. Each of the plurality of through holes 41 provided in the one end portion 401 has a circular opening shape as viewed in a direction perpendicular to a major surface 401a of the one end portion 401, for example.

Also, the plurality of through holes 41 are provided in the matrix configuration in a region S1 of the one end portion 401 of the connecting member 40A.

The area of the region S1 is larger than the area of a surface (a region S2) to which the one end portion 401 of the connecting member 40A is connected in the semiconductor element 20. That is, the semiconductor element 20 is connected to the connecting member 40A within a range of the region S1.

The semiconductor element 20 and the one end portion 401 of the connecting member 40A are joined to each other by the joining material 52. The joining material 52 is solder, for example. Also, the other end portion 402 of the connecting member 40A and the electrode terminal 30A are joined to each other by the joining material 53. The joining material 53 is solder, for example.

Here, the joining material 52 intervenes between the semiconductor element 20 and the connecting member 40A and penetrates into the through holes 41 provided in the connecting member 40A.

As shown in FIG. 1B, the one end portion 401 of the connecting member 40A is supported by a protective insulating film 22 provided on the surface of the semiconductor element 20. The joining material 52 intervenes in a gap between the surface of the semiconductor element 20 and the connecting member 40A generated by being supported by the protective insulating film 22.

Also, if the joining material 52 is solder, the melted joining material 52 is sucked into the through holes 41 by surface tension. As a result, the joining material 52 intervening between the one end portion 401 of the connecting member 40A and the surface of the semiconductor element 20 is prevented from protruding out of the region surrounded by the protective insulating film 22.

In the semiconductor device 110 illustrated in FIGS. 1A and 1B, the connecting member 40B is also provided. The connecting member 40B connects the semiconductor element 20 and the electrode terminal 30B to each other. In the connecting member 40B, too, the plurality of through holes may be provided similarly to the connecting member 40A described above. In the semiconductor device 110 illustrated in FIGS. 1A and 1B, the plurality of through holes 41 are provided only in the connecting member 40A.

In the semiconductor device 110 according to the embodiment, since the plurality of through holes 41 are provided in the connecting member 40A, the joining material 52 penetrates not only between the connecting member 40A and the semiconductor element 20 but also in the through holes 41, whereby protrusion of the joining material 52 can be suppressed. As described above, since the protrusion of the joining material 52 can be suppressed, the connecting member 40A having the one end portion 401 larger than the area of the semiconductor element 20 can be used. That is, connection of the semiconductor element 20 in various sizes can be handled by the large connecting member 40A.

Also, by narrowing the interval between the adjacent connecting members 40A and 40B, short circuit between the both can be prevented. Thus, the interval between the connecting member 40A and the connecting member 40B adjacent thereto can be narrowed, whereby an increase in the size of the semiconductor device 110 can be prevented.

Subsequently, specific examples of each portion will be described.

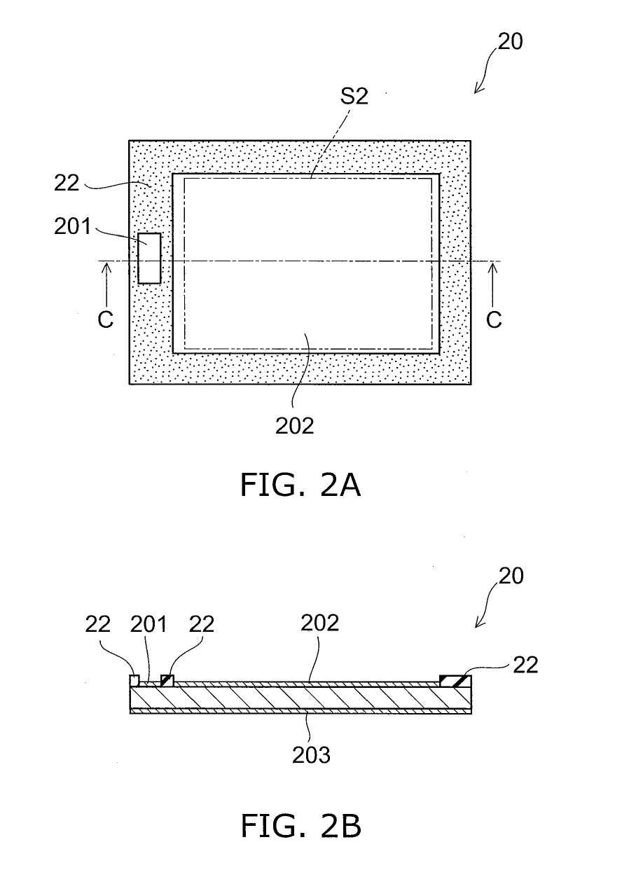

FIGS. 2A and 2B are schematic diagrams for describing the semiconductor element.

FIG. 2A is a schematic plan view of the semiconductor element, and FIG. 2B is a schematic sectional view on arrow of a C-C line shown in FIG. 2A.

The semiconductor element 20 is cut out into the shape of a chip. On the surface of the semiconductor element 20, the protective insulating film 22 is provided. The protective insulating film 22 is provided on a portion excluding electrodes 201 and 202 on the surface of the semiconductor element 20. The protective insulating film 22 is a solder resist (thermosetting resin), for example.

On the back surface of the semiconductor element 20, an electrode 203 is provided. If the semiconductor element 20 is MOSFET, for example, the electrode 201 is a gate electrode, the electrode 202 is a source electrode, and the electrode 203 is a drain electrode, for example. The electrode 201 which becomes the gate electrode is arranged on the peripheral edge part of the front face of the semiconductor element 20, for example. Also, the electrode 202 which becomes the source electrode is provided at the center part on the front face of the semiconductor element 20 having an area wider than that of the electrode 201, for example. Also, the electrode 203 that becomes the drain electrode is provided on the whole surface on the back surface of the semiconductor element 20.

The electrode 203 provided on the back surface of the semiconductor element 20 is joined to the pedestal portion 11 of the base 10 by the joining material 51 shown in FIG. 1B. Also, the electrode 201 provided on the surface of the semiconductor element 20 is joined to the connecting member 40B shown in FIGS. 1A and 1B through the joining material 52.

Also, the electrode 202 provided on the surface of the semiconductor element 20 is joined to the connecting member 40A shown in FIGS. 1A and 1B through the joining material 52. Here, the connecting member 40A is joined to the region S2 of the electrode 202. The region S2 may be the same as the region surrounded by the inner circumference of the protective insulating film 22 or may be a region slightly smaller than that. The area of the region S1 in which the through holes 41 are provided in the connecting member 40A shown in FIG. 1A is wider than the area of the region S2 to which this connecting member 40A is joined. As a result, even in the case of the semiconductor element 20 having a different size, the electrode 202 and the connecting member 40A can be joined to each other inside the region S1 in which the through holes 41 are provided.

As described above, the connecting member 40A is joined to the region S2 which occupies the most part of the electrode 202. Since the connecting member 40A is formed of metal, as the semiconductor element 20 is joined to the connecting member with larger area, the surface resistance of the semiconductor element 20 can be more reduced.

The arrangement of the electrodes 201, 202, and 203 is an example and it is not limiting.

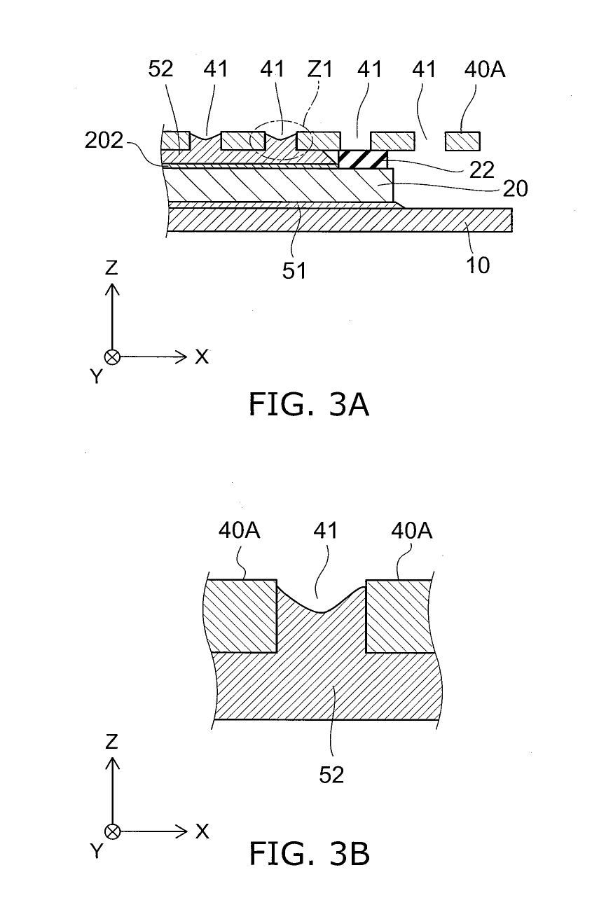

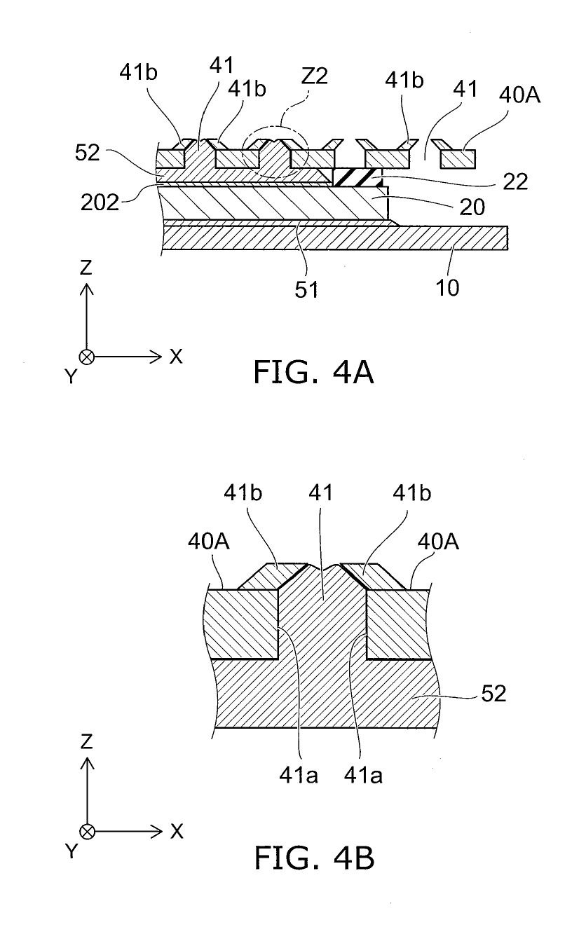

FIGS. 3A and 3B and FIGS. 4A and 4B are schematic sectional diagrams illustrating specific examples of the through holes.

FIGS. 3A and 3B show specific examples in which the through holes are provided in the connecting member, and FIGS. 4A and 4B show specific examples in which the through holes and projections are provided in the connecting member, respectively. FIGS. 3A and 4A are schematic sectional diagrams on arrow of a B-B line in FIG. 1A. FIG. 3B is an enlarged diagram of a one-dot-chain-line frame Z1 in FIG. 3A, and FIG. 4B is an enlarged diagram of a one-dot-chain-line frame Z2 in FIG. 4A.

First, on the basis of FIGS. 3A and 3B, the specific example in which the through holes are provided in the connecting member will be described.

As shown in FIGS. 3A and 3B, the connecting member 40A is supported on the protective insulating film 22 provided on the surface of the semiconductor element 20. Between the electrode 202 and the connecting member 40A, the joining material 52 intervenes.

The joining material 52 is solder, for example, and melts in joining and extends between the electrode 202 and the connecting member 40A. At this time, the joining material 52 is sucked into the though holes 41 by surface tension. As a result, between the electrode 202 and the connecting member 40A, the joining material 52 extending in the direction of the protective insulating film 22 is prevented from protruding to the outside of the protective insulating film 22.

On the other hand, if the through holes 41 are not provided in the connecting member 40A, the melted joining material 52 transmits on the surface of the connecting member 40A and easily flows over the protective insulating film 22 and leaks out. On the contrary, if the through holes 41 are provided in the connecting member 40A as in the embodiment, the melted joining material 52 is pulled into the through holes 41 in the midway of transmission and extension on the surface of the connecting member 40A and is prevented from flowing over the protective insulating film 22.

Also, if solder containing an organic material, for example, is used as the joining material 52, the organic material is volatilized in a gas state by melting of the solder. This volatilized gas easily goes out through the through holes 41. That is, the through holes 41 are used as holes for gas ventilation when the organic material is volatilized.

As described above, since protrusion of the joining material 52 to the outside of the protective insulating film 22 can be prevented, and since the gas generated from the joining material 52 can easily go out through the through holes 41, in the embodiment, the joining material 52 can be provided with a thickness larger than that when the through holes 41 are not provided. If the joining material 52 is provided with a larger thickness, deterioration of the joining material 52 in a heat cycle between the semiconductor element 20 and the connecting member 40A can be suppressed.

Subsequently, on the basis of FIGS. 4A and 4B, the specific example in which the through holes and projections are provided in the connecting member will be described.

As shown in FIGS. 4A and 4B, the plurality of through holes 41 are provided in the connecting member 40A. Also, in each of the through holes 41, a projection 41b is provided, the projection 41b rising from an inner wall 41a of the through hole 41 in the Z direction going forward a side opposite to (upper side of) the semiconductor element 20. That is, the projection 41b rises from the upper edge of the through hole 41.

For such projection 41b, a bur generated in drilling work of the through holes 41 in the connecting member 40A may be used, or processing of providing the projection 41b separately after the drilling work may be performed, for example.

If the projection 41b is provided in the through hole 41, the joining material 52 sucked into the through hole 41 penetrates to the position of the projection 41b on the upper side of the through hole 41. If solder is used for the joining material 52, for example, solder is sucked into the through hole 41 by surface tension of the melted solder. Moreover, the solder is sucked up to the position of the projection 41b.

Here, if the projection 41b rising from the upper edge of one of the through holes 41 is provided such that an opening diameter in the X direction formed from the projection 41b gets smaller as being spaced from the upper edge of the through hole 41, the effect of sucking-up by surface tension of the joining material 52 is made more marked.

As described above, by providing the projection 41b in the through hole 41, the joining material 52 can be made to reliably penetrate to the position of the projection 41b. Therefore, the effect of suppression of protrusion of the joining material 52 to the outside of the protective insulating film 22 can be exerted more effectively. That is, by providing the projection 41b in the through hole 41, the effect of the connecting member 40A illustrated in FIG. 3 can be improved.

Subsequently, specific examples of states of the connecting member according to a difference in the size of the semiconductor element will be described.

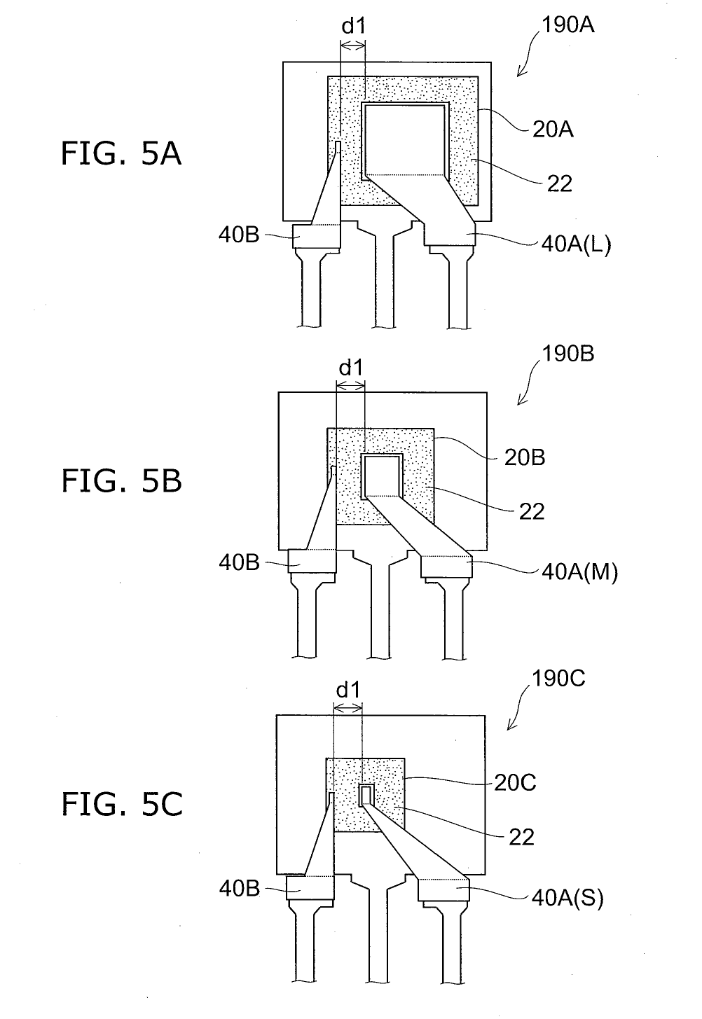

FIGS. 5A to 5C are schematic plan views illustrating a specific example of a semiconductor device in which a through hole is not provided in the connecting member.

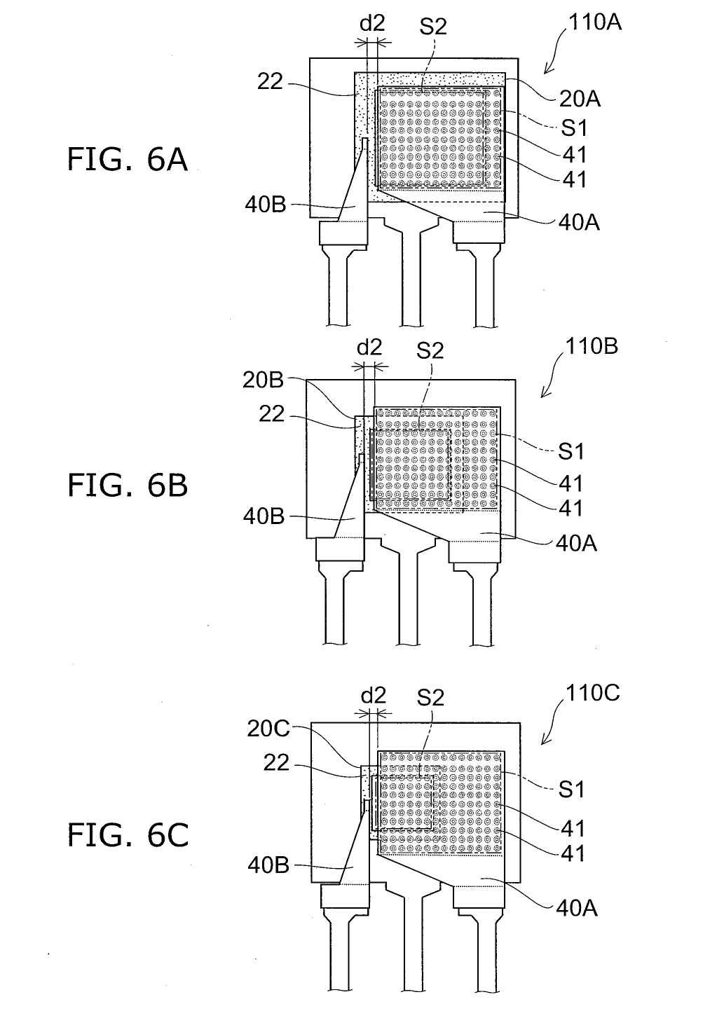

FIGS. 6A to 6C are schematic plan views illustrating a specific example of a semiconductor device in which a through hole is provided in the connecting member.

First, on the basis of FIGS. 5A to 5C, an example in which the through hole is not provided in the connecting member will be described.

From FIG. 5A to FIG. 5C, the size of the semiconductor element (20A, 20B, and 20C) is sequentially decreased.

That is, the size of a semiconductor element 20B of a semiconductor device 190B shown in FIG. 5B is smaller than the size of the semiconductor element 20A of a semiconductor device 190A shown in FIG. 5A. Also, the size of a semiconductor element 20C of a semiconductor element 190C shown in FIG. 5C is smaller than the size of the semiconductor element 20B of the semiconductor device 190B.

Here, the through hole is not provided in the connecting members 40A (L), 40A (M) and 40A(S). Thus, considering probability that the joining material 52 leaks to the outside of the protective insulating film 22, an interval d1 between each of the connecting members 40A (L), 40A (M) and 40A(S) and the connecting member 40B adjacent thereto needs to be provided relatively wide. In accordance with the interval d1, the width of the protective insulating film 22 is set wider.

In the semiconductor elements 20A, 20B, and 20C shown in FIGS. 5A to 5C, in order to ensure the interval d1 to some degree, a contact area with the connecting members 40A (L), 40A (M) and 40A(S) becomes smaller as the element size becomes smaller. In the semiconductor device 190A, 190B, and 190C shown in FIGS. 5A to 5C, the connecting members 40A (L), 40A (M) and 40A(S) which are different in accordance with the contact area between the semiconductor elements 20A, 20B, and 20C and the connecting members 40A (L), 40A (M) and 40A(S) are prepared.

Subsequently, on the basis of FIGS. 6A to 6C, an example in which the through hole is provided in the connecting member will be described.

From FIG. 6A to FIG. 6C, the size of the semiconductor element (20A, 20B, and 20C) is decreased in this order.

That is, the size of the semiconductor element 20B of a semiconductor device 110B shown in FIG. 6B is smaller than the size of the semiconductor element 20A of a semiconductor device 110A shown in FIG. 6A. Also, the size of the semiconductor element 20C of a semiconductor device 110C shown in FIG. 6C is smaller than the size of the semiconductor element 20B of the semiconductor device 110B.

Since the plurality of through holes 41 are provided in the connecting member 40A shown in FIGS. 6A to 6C, leakage of the joining material 52 to the outside of the protective insulating film 22 is suppressed. Thus, an interval d2 between the connecting member 40A and the connecting member 40B adjacent thereto can be made smaller than the interval d1 shown in FIGS. 5A to 5C. The width of the protective insulating film 22 is set in accordance with the interval d2. Therefore, in the semiconductor elements 20A, 20B, and 20C shown in FIGS. 6A to 6C, as compared with the example shown in FIGS. 5A to 5C, the contact area between the semiconductor elements 20A, 20B, and 20C and the connecting member 40A can be made larger.

Also, in the semiconductor elements 20A, 20B, and 20C shown in FIGS. 6A to 6C, since the interval d2 can be made smaller than the interval d1 shown in FIGS. 5A to 5C, even if the element size is smaller, the contact area with the connecting member 40A can be sufficiently ensured.

Moreover, in the connecting member 40A of the semiconductor devices 110A, 110B, and 110C shown in FIGS. 6A to 6C, the area of the region S1 in which the plurality of through holes 41 are provided is larger than the area of the region S2 of joining between the connecting member 40A and the semiconductor elements 20A, 20B, and 20C. Therefore, even if the sizes of the semiconductor elements 20A, 20B, and 20C are different, they can be handled by one type of the connecting member 40A.

Also, the plurality of through holes 41 provided in the connecting member 40A are used for gas ventilation of the joining material 52 by solder, for example, so that the connecting member 40A and the semiconductor elements 20A, 20B, and 20C can be reliably joined to each other by the joining material 52.

Here, in the examples shown in FIGS. 5A to 5C, the largest connecting member 40A(L) is used and connected to the semiconductor element 20C shown in FIG. 5C. In this case, if the joining material 52 by solder is melted, it might transmit on the surface of the connecting member 40A(L) and leak to the outside of the protective insulating film 22.

On the other hand, as shown in FIGS. 6A to 6C, by providing the plurality of through holes 41 in the connecting member 40A, even if melted solder transmits on the surface of the connecting member 40A, it is sucked into the through holes 41, and leakage to the outside of the protective insulating film 22 can be suppressed.

Therefore, in the semiconductor devices 110A, 110B, and 110C shown in FIGS. 6A to 6C, even if the sizes of the semiconductor elements 20A, 20B, and 20C are different, they can be handled by one type of the connecting member 40A. Moreover, since the interval d2 between the connecting member 40A and the connecting member 40B adjacent thereto can be made smaller, the sizes of the semiconductor devices 110A, 110B, and 110C can be reduced.

### Second Embodiment

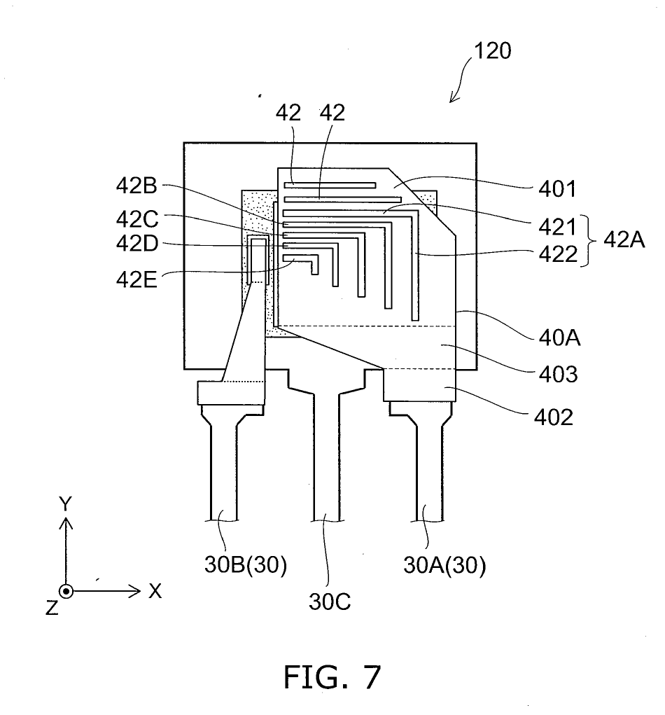

FIG. 7 is a schematic plan view illustrating the configuration of a semiconductor device according to a second embodiment.

As shown in FIG. 7, in a semiconductor device 120 according to the embodiment, an opening shape of each of a through hole 42 is rectangular as viewed in a direction perpendicular to the major surface 401a of the one end portion 401.

That is, the through hole 42 is provided having a rectangular shape on XY plan view.

Also, each of through holes 42A, 42B, 42C, 42D, and 42E is formed by combining a rectangular first through hole 421 extending in the X direction with a rectangular second through hole 422 extending in the Y direction.

The first through hole 421 and the second through hole 422 have their one ends connected to each other and form an L-shape on the XY plan view.

Moreover, among the through holes 42A, 42B, 42C, 42D, and 42E, the through hole 42A is provided on the outermost side, and the through holes 42B, 42C, 42D, and 42E are provided inside the through hole 42A in this order.

Here, the sizes of the first through hole 421 and the second through hole 422 of each of the through holes 42A, 42B, 42C, 42D, and 42E correspond to the size of the electrode 202 of the semiconductor element 20 to which the connecting member 40A is connected. That is, the L-shape formed by the first through hole 421 and the second through hole 422 corresponds to two sides in the electrode 202 in various sizes.

By using the connecting member 40A in which the through holes 42A, 42B, 42C, 42D, and 42E are provided as above, even for the semiconductor element 20 with a different size, at least one of the through holes 42A, 42B, 42C, 42D, and 42E is arranged inside the electrode 202.

Therefore, the joining material 52 intervening between the connecting member 40A and the electrode 202 is sucked into at least one of the through holes 42, 42A, 42B, 42C, 42D, and 42E arranged inside the electrode 202. As a result, the joining material 52 is prevented from leaking to the outside of the protective insulating film 22.

With the connecting member 40A as above, connection of different sizes of the semiconductor elements 20 can be handled by one type of the connecting member 40A.

In the through holes 42A, 42B, 42C, 42D, and 42E illustrated in FIG. 7, one ends of the first through hole 421 and the second through hole 422 are connected to each other, but they do not necessarily have to be connected. Also, the direction of the L shape formed by the first through hole 421 and the second through hole 422 is not limited by that shown in FIG. 7.

### Third Embodiment

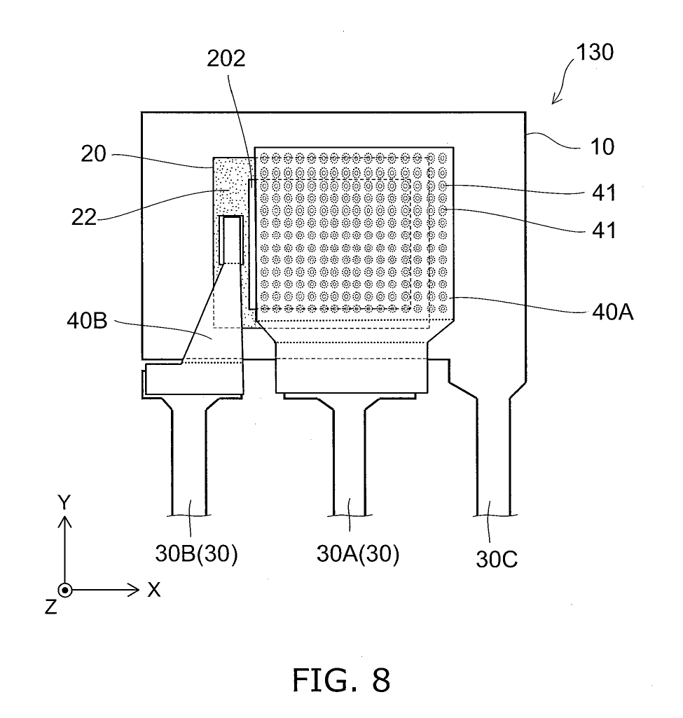

FIG. 8 is a schematic plan view illustrating the configuration of a semiconductor device according to a third embodiment.

As shown in FIG. 8, a semiconductor device 130 according to the embodiment has the electrode terminal 30A arranged at the center of three terminals, and the electrode terminal 30C is arranged at one of the ends of the three terminals.

That is, the electrode terminal 30C extending in the Y direction from the base 10 is arranged at one of the ends of the three terminals. Also, the electrode terminal 30A arranged at the center of the three terminals is connected to the semiconductor element 20 by the connecting member 40A. The electrode terminal 30B arranged at the other end of the three terminals is connected to the semiconductor element 20 by the connecting member 40B.

In the connecting member 40A, a plurality of the through holes 41 are provided. The through holes 41 may have either of the configurations illustrated in FIGS. 3A and 3B and FIGS. 4A and 4B. The connecting member 40A has a shape conforming to the arrangement of the electrode terminal 30A to be connected.

As in the semiconductor device 130, even if the electrode terminal 30A may be arranged at the center of the three terminals, by using the connecting member 40A provided with the through holes 41, the semiconductor element 20 in various sizes can be handled by one connecting member 40A.

### Fourth Embodiment

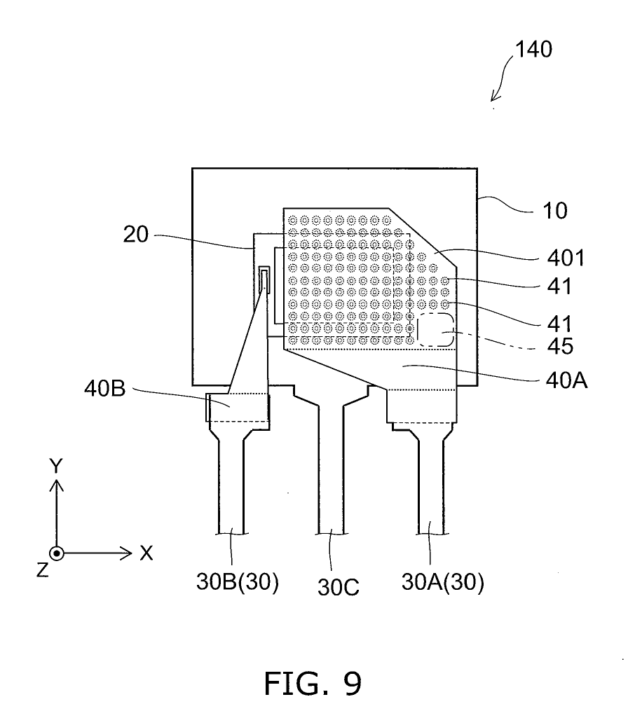

FIG. 9 is a schematic plan view illustrating the configuration of a semiconductor device according to a fourth embodiment.

As shown in FIG. 9, in a semiconductor device 140 according to the embodiment, a flat portion 45 for suction is provided on the connecting member 40A.

The flat portion 45 is provided at the one end portion 401 in which the plurality of through holes 41 are provided in the connecting member 40A. The through hole 41 is not provided in the flat portion 45. The one end portion 401 in which the plurality of through holes 41 are provided occupies a large area in the connecting member 40A. Thus, the center of gravity of the connecting member 40A is biased to the one end portion 401 side.

If the connecting member 40A is to be held by vacuum contact, for example, it is preferably held close to the position of the center of gravity. Here, the plurality of through holes 41 is provided in the one end portion 401 of the connecting member 40A, and air leakage occurs in vacuum contact at the position of the through holes 41. Therefore, in the one end portion 401 close to the position of the center of gravity of the connecting member 40A, the flat portion 45 without the through hole 41 is provided. As a result, even with the connecting member 40A in which the through holes 41 are provided, vacuum contact at the flat portion 45 close to the position of the center of gravity is made possible.

The flat portion 45 is preferably located close to the position of the center of gravity and most preferably matched with the position of the center of gravity. However, since the through hole 41 is not provided in the flat portion 45, the flat portion 45 is preferably arranged at a position which does not interfere with the effect of the through holes 41 as much as possible.

### Fifth Embodiment

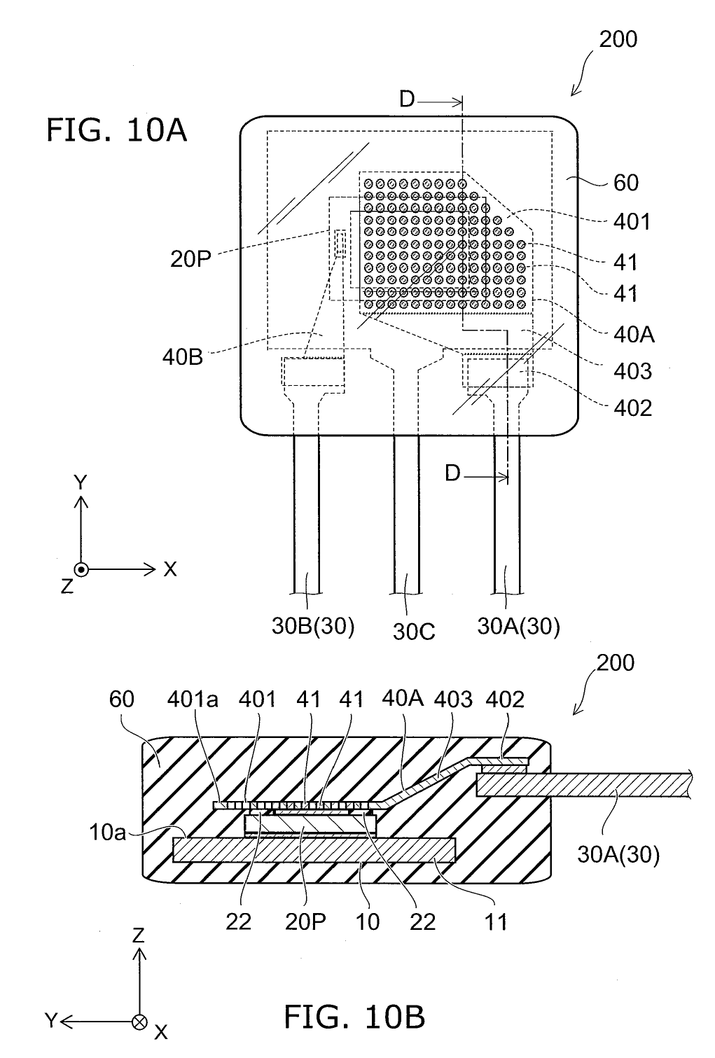

FIGS. 10A to 10B are schematic diagrams illustrating the configuration of a power semiconductor device according to a fifth embodiment.

FIG. 10A is a schematic plan view of the power semiconductor device according to the embodiment, and FIG. 10B is a schematic sectional view on arrow of a D-D line shown in FIG. 10A.

That is, as shown in FIGS. 10A and 10B, the power semiconductor device 200 according to the embodiment includes the base 10, a power semiconductor element 20P mounted on the base 10, the electrode terminal 30A provided spaced from the base 10, the connecting member 40A connecting the power semiconductor element 20P to the electrode terminal 30A and in which the plurality of through holes 41 are provided in a region to be connected to the power semiconductor element 20P, the connecting material 52 intervening between the power semiconductor element 20P and the connecting member 40A and penetrating into the plurality of through holes 41, and a sealing member 60 that seals at least the power semiconductor element 20P.

The power semiconductor element 20P is a transistor element capable of handling high voltage and high current such as IGBT (Insulated Gate Bipolar Transistor), IEGT (Injection Enhanced Gate Transistor), power MOS (Metal Oxide Semiconductor) transistor and the like. In the power semiconductor device 200 according to the embodiment, the IGBT is applied as an example of the power semiconductor element 20P.

The power semiconductor element 20P is connected to the pedestal portion 11 of the base 10 by the joining material 51, which is solder, for example. A connection face (back surface) of the power semiconductor element 20P with the pedestal portion 11 is a collector of the IGBT. On the pedestal portion 11, the electrode terminal 30C extending to the outside of the sealing member 60 is provided. Therefore, the electrode terminal 30C is used as a collector electrode of the power semiconductor device 200.

In the power semiconductor device 200 illustrated in FIGS. 10A to 10B, two more electrode terminals 30A and 30B are provided. The electrode terminal 30A is connected to the power semiconductor element 20P by the connecting member 40A. Also, the electrode terminal 30B is connected to the power semiconductor element 20P by the connecting member 40B. One of the electrode terminals 30A and 30B is used as an emitter electrode or a base electrode of the power semiconductor device 200, while the other is used as the base electrode or the emitter electrode of the power semiconductor device 200.

The connecting member 40A has the one end portion 401 connected to the semiconductor element 20, the other end portion 402 connected to the electrode terminal 30A, and the intermediate portion 403 provided between the one end portion 401 and the other end portion 402.

The one end portion 401 is provided substantially in parallel with the surface of the power semiconductor element 20P. Also, the other end portion 402 is provided substantially in parallel with the surface of the electrode terminal 30A. Also, the intermediate portion 403 is bent with respect to the one end portion 401 and the other end portion 402 as necessary, and a difference is provided in height in the Z direction between the one end portion 401 and the other end portion 402.

The plurality of through holes 41 are provided in the one end portion 401 of the connecting member 40A. The power semiconductor element 20P and the one end portion 401 of the connecting member 40A is joined by the joining material 52. The joining material 52 is solder, for example. Also, the other end portion 402 of the connecting member 40A and the electrode terminal 30A are joined by the joining material 53. The joining material 53 is solder, for example.

Here, the joining material 52 intervenes between the power semiconductor element 20P and the connecting member 40A and also penetrates into the through holes 42 provided in the connecting member 40A.

As shown in FIG. 10B, the one end portion 401 of the connecting member 40A is supported by the protective insulating film 22 provided on the surface of the power semiconductor element 20P. The joining material 52 intervenes in a gap formed between the surface of the semiconductor element 20 and the connecting member 40A generated by being supported by the protective insulating film 22.

Also, the joining material 52 is sucked into the through holes 41 by surface tension. As a result, the joining material intervening between the one end portion 401 of the connecting member 40A and the surface of the semiconductor element 20 is prevented from protruding to the outside of the connecting member 40A.

The sealing member 60 seals at least the power semiconductor element 20P. For the sealing member 60, an epoxy resin is used, for example. In the embodiment, a part of the power semiconductor element 20P, the base 10, the electrode terminal 30A, 30B, and 30C are sealed by the sealing member 60.

In the power semiconductor device 200 according to the embodiment, protrusion of the joining material 52 can be suppressed by the connecting member 40A in which the plurality of through holes 41 are provided. As a result, the connecting member 40A having the one end portion 401 larger than the area of the power semiconductor element 20P can be used, and connection of various sizes of the power semiconductor element 20P can be handled by one connecting member 40A.

Also, by reducing the interval between the adjacent connecting members 40A and 40B, too, short-circuit between the both can be prevented. Thus, even if the large connecting member 40A is used, the interval with the adjacent connecting member 40B does not have to be expanded unnecessarily, and size increase of the power semiconductor device 200 can be prevented.

Also, by using the connecting member 40A having the one end portion 401 larger than the power semiconductor element 20P, heat generated in the power semiconductor element 20P can be easily emitted to the outside through the connecting member 40A. That is, heat radiation characteristics of the power semiconductor device 200 can be improved.

Moreover, ON resistance of the power semiconductor element 20P such as the IGBT can be reduced by an increase in the contact area between the electrode 202 and the connecting member 40A.

In the power semiconductor device 200 illustrated in FIGS. 10A and 10B, the connecting member 40A provided with the circular through holes 41 is used, but the connecting member 40A provided with the rectangular through holes 42, 42A, 42B, 42C, 42D, and 42E may be used. Also, the power semiconductor device 200 may be the one in which a plurality of the power semiconductor elements 20P are mounted on the base 10 other than those in which one power semiconductor element 20P is mounted on the base 10.

### (Variation of Connecting Member and Electrode Terminal)

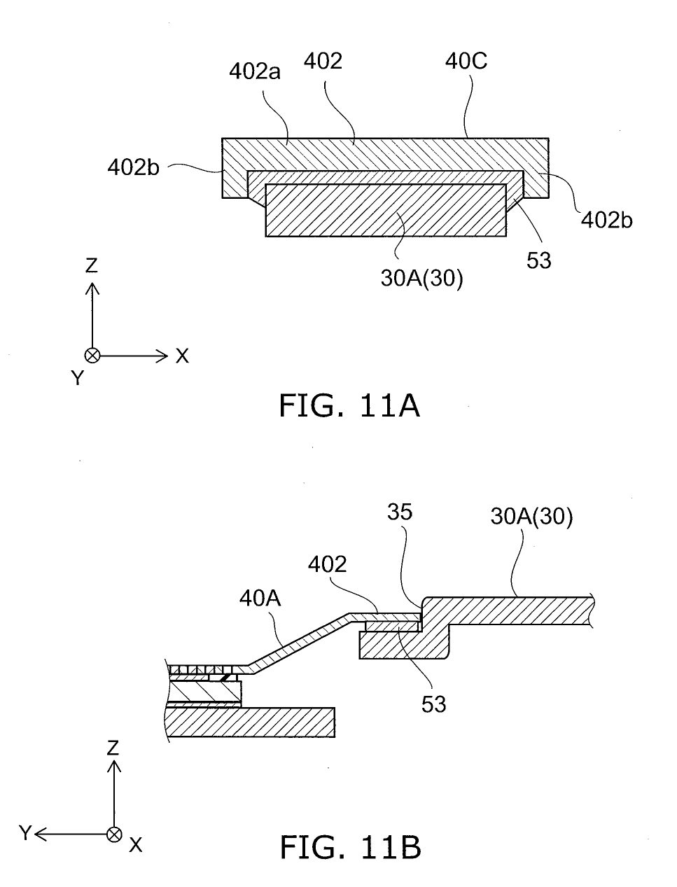

FIGS. 11A and 11B are schematic diagrams for describing a variation of the connecting member and the electrode terminal.

FIG. 11A is a schematic diagram on the XZ plane in the other end portion of the connecting member. FIG. 11B is a schematic sectional view on the YZ plane of the electrode terminal.

In a connecting member 40C shown in FIG. 11A, the other end portion 402 has a first surface 402a connected to the electrode terminal 30A and a second surface 402b provided on the first face 402a and adjacent to the side face of the electrode terminal 30A.

The second face 402b is provided on both ends in the X direction of the first face 402a.

By using the connecting member 40C, when the other end portion 402 of the connecting member 40C is joined to the electrode terminal 30A through the joining material 53, the outside of the side faces of the electrode terminal 30A is surrounded by the two second faces 402b. Therefore, when the connecting member 40C is to be arranged, the position in the X direction with respect to the electrode terminal 30A is regulated.

Also, if the connecting member 40C is joined to the electrode terminal 30A through the joining material 53 by solder, the joining material 53 melted between the first face 402a and the electrode terminal 30A expands the outside and penetrates into between the second faces 402b and the side faces of the electrode terminal 30A. As a result, protrusion of the joining material 53 can be suppressed.

In the electrode terminal 30A shown in FIG. 11B, a stepped portion 35 is provided in the middle. The stepped portion 35 is a portion provided so that the middle of the electrode terminal 30A rises in the Z direction. When the connecting member 40A is to be joined to the electrode terminal 30A, the distal end of the other end portion 402 of the connecting member 40A is abutted to the stepped portion 35 of the electrode terminal 30A. As a result, when the connecting member 40A is to be arranged, the position in the Y direction with respect to the electrode terminal 30A is regulated.

As described above, according to the semiconductor devices 110, 120, 130, and 140 and the power semiconductor device 200 according to the embodiments, the semiconductor element 20 in various sizes can be mounted by using one type of the connecting member 40A.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a base;
a semiconductor element mounted on the base;
an electrode terminal provided spaced from the base;
a connecting member connecting the semiconductor element to the electrode terminal and including a plurality of through holes provided in one end portion of the connecting member, the one end portion being connected to the semiconductor element; and
a joining material intervening between the semiconductor element and the connecting member and penetrating into the plurality of through holes.

2. The device according to claim 1, wherein
an area of a region where the plurality of through holes are provided in the one end portion is larger than an area of a connection face with the connecting member in the semiconductor element.

3. The device according to claim 1, wherein
the connecting member has a projection rising toward a side opposite to the semiconductor element from an inner wall, of each of the through holes; and
the joining material penetrates to a position of the projection from the through hole on a side of the semiconductor element.

4. The device according to claim 3, wherein
a diameter of an opening formed by the projection is becoming smaller as being away from the through hole.

5. The device according to claim 1, wherein
the connecting member has a first face connected to the surface of the electrode terminal and a second face provided on the first face and adjacent to a side face of the electrode terminal.

6. The device according to claim 1, wherein
the electrode terminal has a stepped portion on which a distal end of the connecting member abuts.

7. The device according to claim 1, wherein
the connecting member has a flat portion in which the through holes are not provided.

8. The device according to claim 1, wherein
an opening shape of the each of the through holes is circular as viewed in a direction perpendicular to a major surface of the one end portion.

9. The device according to claim 1, wherein
an opening shape of the each of the through holes is rectangular as viewed in a direction perpendicular to a major surface of the one end portion.

10. The device according to claim 9, wherein
the each of the through holes has a first through portion extending in a first direction along the major surface and a second through portion extending in a second direction along the major surface and orthogonal to the first direction.

11. The device according to claim 10, wherein
the each of the through holes is provided in an L-shape configuration in which one end of the first through portion is connected to one end of the second through portion.

12. The device according to claim 11, wherein
the plurality of through holes are provided in L-shape configuration with different sizes.

13. The device according to claim 1, wherein
the plurality of through holes are provided in a matrix configuration on the one end portion.

14. The device according to claim 1, further comprising:
a protective insulating film provided on the surface of the semiconductor element; and
the one end portion is supported by the protective insulating film.

15. The device according to claim 14, wherein
the joining material is provided in a region surrounded by the protective insulating film.

16. A power semiconductor device, comprising:
a base;
a power semiconductor element mounted on the base;
an electrode terminal provided spaced from the base;
a connecting member connecting the power semiconductor element to the electrode terminal and including a plurality of through holes provided in one end portion of the connecting member, the one end portion being connected to the power semiconductor element;
a joining material intervening between the power semiconductor element and the connecting member and penetrating into the plurality of through holes; and
a sealing member sealing at least the power semiconductor element.
